(19) United States
(12) Patent Application Publication
(10) Pub. No.: US 2025/0028685 A1
(43) Pub. Date: Jan. 23, 2025

(54) LOSSLESS COMPRESSION AND DECOMPRESSION METHOD FOR DATA

(71) Applicant: JIANYI LI, Guangzhou (CN)

(72) Inventor: JIANYI LI, Guangzhou (CN)

(21) Appl. No.: 18/537,664

(22) Filed: Dec. 12, 2023

(30) Foreign Application Priority Data
Jul. 18, 2023 (CN) 202310887083.X

(51) Int. Cl. G06F 16/174

(52) U.S. Cl. CPC G06F 16/1744

(57) ABSTRACT

The present disclosure proposes a lossless compression and decompression method for data including: obtaining raw data, reading the first eight bytes of the raw data, obtaining a first to-be-processed data, obtaining a second to-be-processed data through adding a condition by data, obtaining data A based on a data length of the second to-be-processed data; obtaining remaining data in the second to-be-processed data except for the last four bytes and saving it as data B; performing a rule operation on the last four bytes of the second to-be-processed data to obtain data C; arranging, combining and calculating based on a reference digit of the last four bytes of the second to-be-proceeded data to obtain data D; obtaining compressed data by a formula of data A plus data B plus data C plus data D. It can solve problems that current compression software cannot repeat lossless compression.

### CROSS-REFERENCE TO RELATED APPLICATIONS

This application claims priority to Chinese Patent Application No. 202310887083.X, filed on Jul. 18, 2023, which is hereby incorporated by reference in its entirety.

### TECHNICAL FIELD

The present disclosure relates to the field of data processing technologies, and in particular, to a lossless compression and decompression method for data.

### BACKGROUND

At present, most data compression algorithms are fused or mutated based on LZ77 algorithm and Huffman algorithm. Some compression algorithms are fast but have low compression rates, while others are the opposite. Moreover, it is divided into lossy compression (data will be lost after compression, it may be applied to videos, images, audio files, etc.) and lossless compression (data will not be lost after compression, and it may be applied to system files, executable programs, etc.). All existing algorithms that require statistical data before compression, then it can be performed. For irregular and low repetition rate data, the compression rate is very low, so all algorithms can only compress once.

### SUMMARY

The purpose of the present disclosure is to provide a lossless compression and decompression method for data, which can solve the problem of current compression software that cannot be able to repeat lossless compression and it can perform multiple compressions.

To solve the above technical problems, the technical solution adopted by the present disclosure is as follows.

In a first aspect of the present disclosure, an embodiment of the present application provides a lossless compression method for data, which includes the following steps.

S101. reading a to-be-compressed file, obtaining raw data in hexadecimal of the file, reading the first eight bytes of the raw data to obtain a first to-be-processed data; S102. determining whether there is at least one digit in the first to-be-processed data that satisfies 0-F; selecting sequentially a half byte from the ninth byte of the raw data and adding it to a tail part of the first to-be-processed data until the condition is met to obtain a second to-be-processed data when the at least one digit in the first to-be-processed data does not satisfy 0-F, or taking the first to-be-processed data as the second to-be-processed data when the at least one digit in the first to-be-processed data satisfies 0-F; S103. obtaining a data length based on the second to-be-processed data, converting it to hexadecimal, saving it as data A; obtaining remaining data in the second to-be-processed data except for the last four bytes and saving it as data B; S104. selecting the last four bytes of the second to-be-processed data and performing a rule operation to obtain a third calculation result; converting the third calculation result to hexadecimal and saving it as data C; S105. obtaining a reference digit of the last four bytes of the second to-be-processed data, arranging and combining the reference digit in an orderly manner according to a setting rule, saving a calculation result as all combinations of the third calculation result; searching for a combination of the last four bytes of the second to-be-processed data from a saved combination, obtaining its arrangement rank; converting the arrangement rank to hexadecimal and saving it as data D; S106. obtaining compressed data according to a formula of data A plus data B plus data C plus data D; S107. selecting sequentially next eight bytes from the raw data that has never been read, repeating steps S102-S106 until all bytes have been selected and ending an operation.

Based on the first aspect, the selecting sequentially next eight bytes from the raw data that has never been read, repeating steps S102-S106 until all bytes have been selected and ending an operation includes:
adding missing digit in 0-F to a tail part of the data when a last selected data supplements eight bytes.

Based on the first aspect, the converting the arrangement rank to hexadecimal and saving it as data D includes:
supplementing 0 when the data D is less than two bytes.

Based on the first aspect, the selecting the last four bytes of the second to-be-processed data and performing a rule operation to obtain a third calculation result includes:
selecting the first half byte data and the second half byte data of the last four bytes of the second to-be-processed data, comparing the first half byte data with the second half byte data, performing a large reduction rule operation to obtain a first calculation result; comparing a size of the first calculation result with the third half byte data, performing the larger reduction rule operation to obtain a second calculation result; repeating sequentially until all data has been calculated, and obtaining the third calculation result.

In a second aspect of the present application an embodiment of the present application provides a lossless decompression method for data, which includes the following steps.

S201. reading a to-be-decompressed file in hexadecimal and obtaining a third to-be-processed data; S202. converting the first byte data of the third to-be-processed data to decimal to obtain a first data; obtaining a calculation length based on the first data, reading data from the second byte of the third to-be-processed data according to the calculation length, obtaining a fourth to-be-processed data, and saving the fourth to-be-processed data as data E; S203. retrieving the fourth to-be-processed data, determining missing digit in 0-F of the fourth to-be-processed data, and combining according to a setting rule to obtain a second data; S204. reading data in a first position of the first byte of the third to-be-processed data that has not been read, converting it to decimal to obtain a third data; continuing to read the last two bytes, converting it to decimal to obtain a fourth data; S205. taking the second data as a reference digit, enumerating all combinations and performing a rule operation, saving a calculation result as all combinations of the third data; reading a ranking of a saved combination and taking it as a combination of the fourth data, saving it as data F; S206. obtaining decompressed data according to a formula of data E plus data F; S207. repeating steps S202-S206 for the third to-be-processed data that has not been read until it cannot be read again.

Based on the second aspect, the obtaining a calculated length based on the first data, reading data from the second byte of the third to-be-processed data according to the calculated length and obtaining a fourth to-be-processed data includes:
subtracting the first data by eight to obtain a calculation result M; dividing the calculation result M by two to obtain a calculation result N; calculating a byte length data of the calculation result N reading from the second byte of the third to-be-processed data.

In a third aspect of the present application, an embodiment of the present application provides an electronic device including at least one processor, at least one memory, and a data bus; where, the processor and the memory communicate with each other through the data bus; the memory stores a program instruction executed by the processor, which calls the program instruction to execute any method as described in the first aspect or the second aspect.

In a fourth aspect of the present application, an embodiment of the present application provides a computer readable storage medium, where a computer program is stored thereon, the computer program implements the method as described in any of the first aspect or the second aspect when is executed by a processor.

Compared to the prior art, the present disclosure has at least the following advantages or beneficial effects:
the present disclosure proposes a lossless compression method for data. By obtaining raw data and reading the first eight bytes of the raw data, the first to-be-processed data is obtained, and the second to-be-processed data is obtained through adding a condition by the data. Data A is obtained based on the data length of the second to-be-processed data; the remaining data in the second to-be-processed data except for the last four bytes is further obtained, and it is saved as data B; a rule operation is further performed on the last four bytes of the second to-be-processed data to obtain data C; according to the reference digit of the last four bytes of the second to-be-processed data, them are arranged and combined to obtain data D; the compressed data is finally obtained according to the formula of data A plus data B plus data C plus data D. It can solve the problem that current compression software cannot be able to repeat lossless compression, and it can perform multiple compressions.

### BRIEF DESCRIPTION OF DRAWINGS

In order to provide a clearer explanation of the technical solution of the embodiments of the present disclosure, a brief introduction will be given to the drawings required in the embodiments. It should be understood that the following drawings only illustrate some embodiments of the present disclosure, and therefore should not be regarded as limiting the scope. For ordinary technical personnel in the art, other relevant drawings can also be obtained based on these drawings without creative work.

FIG. 1 is a flowchart of a lossless compression method for data of an embodiment of the present disclosure.

FIG. 2 is a flowchart of a lossless decompression method for data of an embodiment of the present disclosure.

FIG. 3 is a logical flowchart of the lossless compression method for data of an embodiment of the present disclosure.

FIG. 4 is a logical flowchart of the lossless decompression method for data of an embodiment of the present disclosure.

FIG. 5 is a structural block diagram of an electronic device provided by an embodiment of the present disclosure.

Numeral reference: 1. Processor; 2. Memory; 3. Data bus.

### DESCRIPTION OF EMBODIMENTS

In order to render the purpose, technical solution, and advantages of the embodiments of the present application clearer, the following will provide a clear and complete description of the technical solution in the embodiments of the present application in combination with the drawings. It is obvious that the described embodiments are a part of the embodiments of the present application, not all of them. The components of the embodiments of the present application, typically described and shown in the drawings, can be arranged and designed in various different configurations.

The following will provide a detailed explanation of some embodiments of the present application in combination with the drawings. Without conflict, the following embodiments and their respective features can be combined with each other.

### Embodiment 1

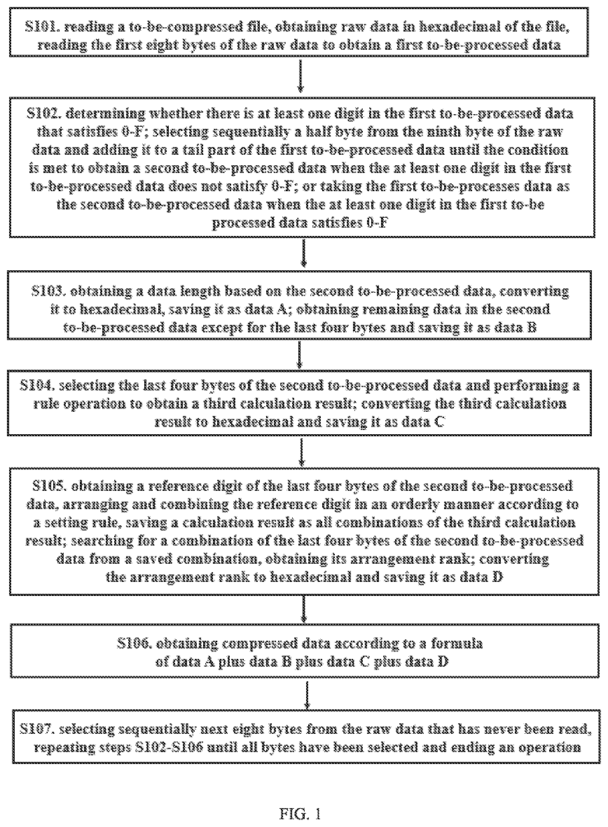

Please refer to FIG. 1. An embodiment of the present application provides a lossless compression method for data, which can solve the problem that current compression software cannot repeat lossless compression, and it can perform infinite compression. This lossless compression method for data includes the following steps:

Step S101: reading a to-be-compressed file, obtaining raw data in hexadecimal of the file, reading the first eight bytes of the raw data to obtain a first to-be-processed data.

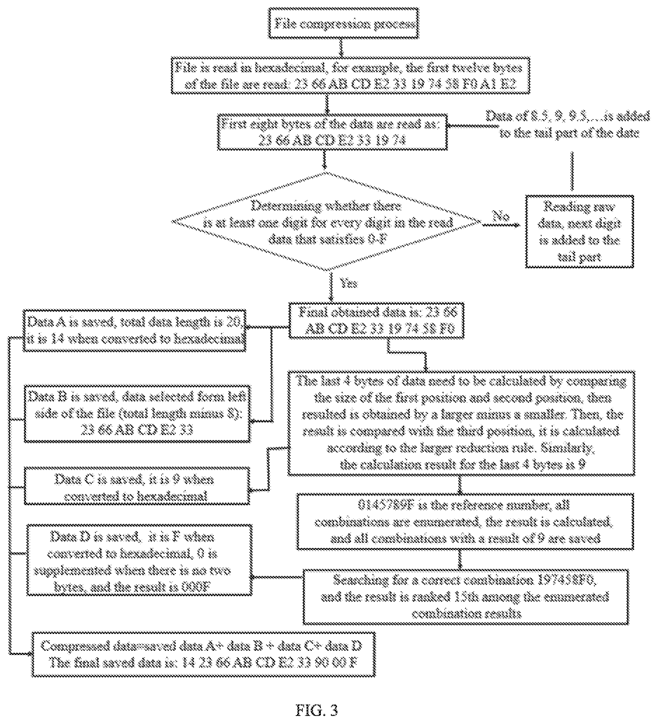

In the above steps, the file is firstly read in hexadecimal. For example, the first twelve bytes of the file are read: 23 66 AB CD E2 33 19 74 58 F0 A1 E2, and the first eight bytes of the data are read as: 23 66 AB CD E2 33 19 74, please refer to FIG. 3.

Step S102: determining whether there is at least one digit in the first to-be-processed data that satisfies 0-F. If not, selecting sequentially a half byte from the ninth byte of the draw data and adding it to a tail part of the first to-be-processed data until the condition is met to obtain a second to-be-processed data; when the condition is satisfied, taking the first to-be-processed data as the second to-be-processed data.

In the above steps, it is determined whether there is at least one digit in 0-F for the byte data of 23 66 AB CD E2 33 19 74. It is obvious that the selected data does not meet the condition, so next half byte of the raw data is continued to select, and it is added to the tail part of 23 66 AB CD E2 33 19 74 to obtain 5 bytes of data of 23 66 AB CD E2 33 19 74. However, if 23 66 AB CD E2 33 19 74 5 still does not meet the condition, the above steps are continued, byte data of 23 66 AB CD E2 33 19 74 58, 23 66 AB CD E2 33 19 74 58 F, and 23 66 AB CD E2 33 19 74 58 F0 are sequentially obtained. At this time, if 23 66 AB CD E2 33 19 74 58 F0 meets the condition, then 23 66 AB CD E2 33 19 74 58 F0 is the second to-be-processed data, please refer to FIG. 3.

Step S103: obtaining a data length based on the second to-be-processed data, converting it to hexadecimal, saving it as data A; obtaining remaining data in the second to-be-processed data expect for the last four bytes and saving it as data B.

In the above steps, it can be seen that the data length of bytes 23 66 AB CD E2 33 19 74 58 F0 is 20, and when converted to hexadecimal, it is 14. Then, 14 is saved as data A. The last four bytes is subtracted from 23 66 AB CD E2 33 19 74 58 F0, and then data B is 23 66 AB CD E2 33, as shown in FIG. 3.

Step S104: Selecting the last four bytes of the second to-be-processed data and preforming a rule operation to obtain a third calculation result; converting the third calculation result to hexadecimal and saving it as data C.

Where, the selecting the last four bytes of the second to-be-processed data and performing a rule operation to obtain a third calculation result includes:
selecting the first half byte data and the second half byte data of the last four bytes of the second to-be-processed data, comparing the first half byte data with the second half byte data, performing a large reduction rule operation to obtain a first calculation result; comparing a size of the first calculation result with the third half byte data, performing the larger reduction operation to obtain a second calculation result; repeating sequentially until all data has been calculated, and obtaining the third calculation result.

In the above steps, the last four bytes of the data is selected as 19 74 58 F0, the calculation mode is compared by a size of the first half byte data (1) with the second half byte data (9), and then a large reduction rule calculation is performed, i.e., 9-1. The first calculation result (8) is obtained, and this result (8) is compared with the third half byte data (7), the calculation is continued according to the large reduction rule. The second calculation result (1) is obtained (i.e., 8-7), and then this result (1) is compared with the fourth half byte data (4), the calculation is continued according to the larger reduction rule, and then 3 is obtained, it is sequentially repeated until the data has been calculated, and then 5−3=2, 8−2=6, F-6=9; thus, the third calculation result is 9. Finally, 9 is saved as data C, as shown in FIG. 3.

Step S105: obtaining a reference digit of the last four bytes of the second to-be-processed data, arranging and combining the reference digit in an orderly manner according to a setting rule, saving a calculation result as all combinations of the third calculation result; searching for a combination of the last four bytes of the second to-be-processed data from a saved combination, obtaining its ranking; converting an arrangement rank to hexadecimal and saving it as data D.

In the above steps, the reference digit for the last four bytes of the second to-be-processed data is 0145789F. All combinations are enumerated, the result is calculated, and all combinations of a result being 9 are saved. A rank of a correct combination 197458F0 from the combinations of the result being 9 is further searched, and the result ranked 15th among the enumerated combination results is obtained. It is F when 15 is further converted to hexadecimal; if it is less than two bytes, 0 is supplemented, then the result is 000F, and finally, byte data of 000F is saved as data D, as shown in FIG. 3.

Step S106: obtaining compressed data according to a formula of data A plus data B plus data C plus data D.

In the above steps, the compressed data for the first ten bytes of the final file is data A plus data B plus data C plus data D, i.e., 14 23 66 AB CD E2 33 90 00 F, as shown in FIG. 3.

Step S107: selecting sequentially next eight bytes from the raw data that has never been read, repeating steps S102-S105 until all bytes have been selected and ending an operation.

Where, the selecting sequentially next eight bytes from the raw data that has never been read, repeating steps S102-S105 until all bytes have been selected and ending an operation includes:

adding missing digit in 0-F to a tail part of the data when a last selected data supplements eight bytes.

In the above steps, considering that the above steps only compressed the first ten bytes of an example file, it is necessary to continue selecting the next eight bytes from A1 and repeat the steps S102-S106 until all bytes have been selected to complete the file compression. If the last selected data is less than eight bytes, a digit that is not included in 0-F is added to the tail part of the data. Since there are sixteen digits in 0-F, the added data meets the eight-byte calculation method. The order of added digit here is preferably the same as the above enumeration order, and it can combine the enumeration method to reduce compression and decompression time. The second last byte and the first last byte of the entire compressed data respectively record the data length and compression frequency after being added; and thus, providing data support for subsequent decompression.

### Embodiment 2

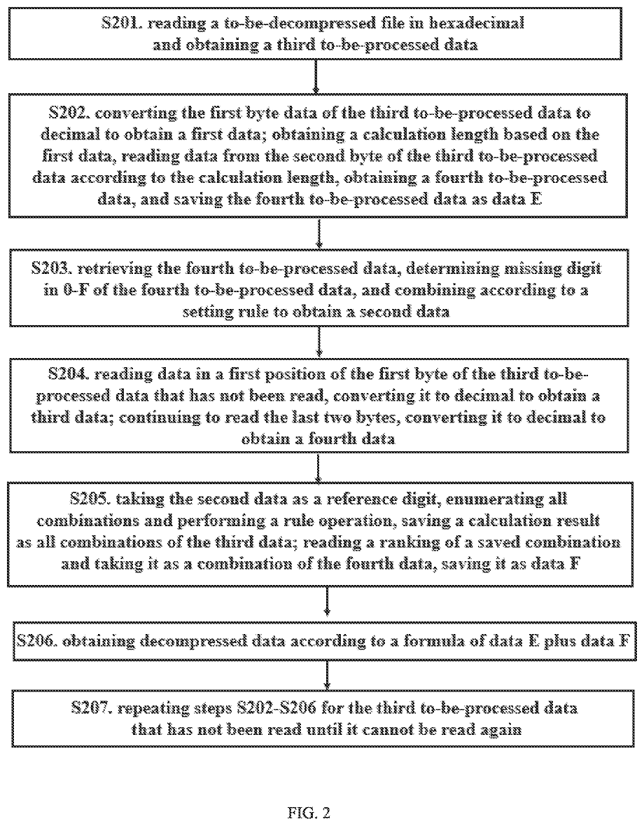

Please refer to FIG. 2. An embodiment of the present application provides a lossless decompression method for data, including the following steps:

Step S201: reading a to-be-decompressed file in hexadecimal and obtaining a third to-be-processed data.

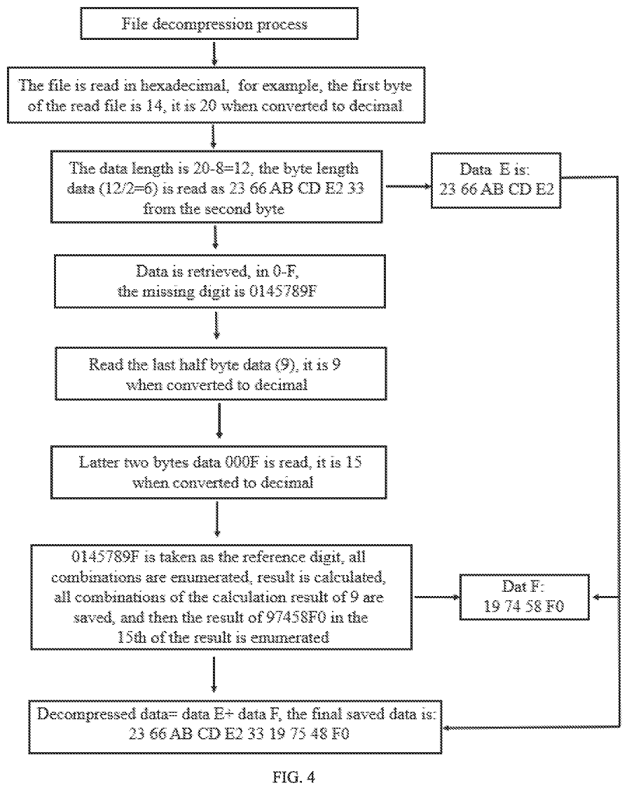

In the above steps, for example, the to-be-decompressed file read in hexadecimal is 14 23 66 AB CD E2 33 90 00 F, please refer to FIG. 4.

Step S202: converting the first byte data of the third to-be-processed data to decimal to obtain a first data; obtaining a calculated length based on the first data, reading data from the second byte of the third to-be-processed data according to the calculation length, obtaining a fourth to-be-processed data, and saving the fourth to-be-processed data as data E.

Where, the obtaining a calculation length based on the first data, reading data from the second byte of the third to-be-processed data according to the calculation length and obtaining a fourth to-be-processed data includes:

subtracting the first data by eight to obtain a calculation result M; dividing the calculation result M by two to obtain a calculation result N; calculating a byte length data of the calculation result N reading from the second byte of the third to-be-processed data.

In the above steps, the first byte data 14 of the third to-be-processed data is converted to decimal, then it is 20, and the data length is 20−8=12. The byte length data (12/2=6) is read as 23 66 AB CD E2 33 from the second byte, and 23 66 AB CD E2 33 is saved as data E, as shown in FIG. 4.

Step S203: retrieving the fourth to-be-processed data, determining missing digit in 0-F of the fourth to-be-processed data, and combining according to a setting rule to obtain a second data.

In the above steps, data retrieval was performed on 23 66 AB CD E2 33, and it was found that in 0-F, the missing digit for 23 66 AB CD E2 33 is 0145789F, which is saved as the second data. Please refer to FIG. 3. The setting rule is arranged from small to large.

Step S204: reading data in a first position of the first byte of the third to-be-processed data that has not been read, converting it to decimal to obtain a third data; continuing to read the last two bytes, converting it to decimal to obtain a fourth data.

In the above steps, the data in first position data of the third to-be-processed data that has not been read is 9, where the data in first position is the first half byte data of the byte. Then 9 is converted to decimal, it is 9 and it is saved as the third data. Then the next two bytes of data 000F is read, and it is converted to decimal, and then it is 15, and it is saved as the fourth data, as shown in FIG. 4.

Step S205: taking the second data as a reference digit, enumerating all combinations and performing a rule operation, saving a calculation result as all combinations of the third data, reading a ranking of a saved combination and taking it as a combination of the fourth data, saving it as data F.

In the above steps, 0145789F is taken as the reference digit, all combinations are enumerated, all combinations of the calculation result being 9 are saved, and then the combination in the 15th of the enumeration result is read as 197458F0, and 197458F0 is saved as data F, as shown in FIG. 4.

Step S206: obtaining decompressed data according to a formula of data E plus data F.

In the above steps, the first ten bytes of decompressed data in the decompressed file are data E plus data F, i.e., 23 66 AB CD E2 33 19 74 58 F0, please refer to FIG. 4.

Step S207: repeating steps S2-S5 for the third to-be-processed data that has not been read until it cannot be read again.

In the above steps, considering that only the first ten bytes of the example file were decompressed, it is necessary to continue repeating steps S202-S206 until all byte data has been read and the file decompression is completed. If there is a record of the adding length in the decompressed data, it can be deleted accordingly. If there is also a record of the decompression times in the decompressed data, it can be decompressed accordingly.

### Embodiment 3

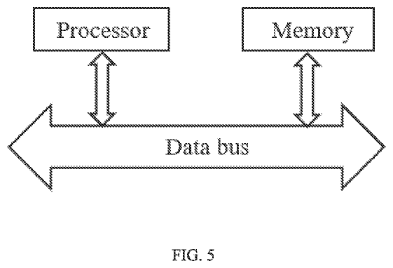

Please refer to FIG. 5. An embodiment of the present application provides an electronic device, which includes at least one processor 1, at least one memory 2, and a data bus 3; where the processor 1 and the memory 2 communicate with each other through the data bus 3; the memory 2 stores a program instruction that can be executed by the processor 1, which calls the program instruction to implement a lossless compression and decompression method of data. For example, to implement the following steps:

S101. reading a to-be-compressed file, obtaining raw data in hexadecimal of the file, reading the first eight bytes of the raw data to obtain a first to-be-processed data; S102. determining whether there is at least one digit in the first to-be-processed data that satisfies 0-F; selecting sequentially a half byte from the ninth byte of the raw data and adding it to a tail part of the first to-be-processed data until the condition is met to obtain a second to-be-processed data when the at least one digit in the first to-be-processed data does not satisfy 0-F; or taking the first to-be-processes data as the second to-be-processed data when the at least one digit in the first to-be processed data satisfies 0-F; S103. obtaining a data length based on the second to-be-processed data, converting it to hexadecimal, saving it as data A; obtaining remaining data in the second to-be-processed data except for the last four bytes and saving it as data B; S104. selecting the last four bytes of the second to-be-processed data and performing a rule operation to obtain a third calculation result; converting the third calculation result to hexadecimal and saving it as data C; S105. obtaining a reference digit of the last four bytes of the second to-be-processed data, arranging and combining the reference digit in an orderly manner according to a setting rule, saving a calculation result as all combinations of the third calculation result; searching for a combination of the last four bytes of the second to-be-processed data from a saved combination, obtaining its arrangement rank; converting the arrangement rank to hexadecimal and saving it as data D; S106. obtaining compressed data according to a formula of data A plus data B plus data C plus data D; S107. selecting sequentially next eight bytes from the raw data that has never been read, repeating steps S102-S106 until all bytes have been selected and ending an operation.

Where, the memory 2 can be, but is not limited to, a Random Access Memory (RAM), a Read Only Memory (ROM), a Programmable Read Only Memory (PROM), an Erasable Programmable Read Only Memory (EPROM), an Electric Erasable Programmable Read Only Memory (EEPROM), etc.

The processor 1 can be an integrated circuit chip with signal processing capabilities. The processor 1 can be a general-purpose processor, including a Central Processing Unit (CPU), a Network Processor (NP), etc.; it can also be a Digital Signal Processing (DSP), an Application Specific Integrated Circuit (ASIC), a Field Programmable Gate Array (FPGA), or other programmable logic devices, gate or transistor logic devices, or discrete hardware components.

It can be understood that the configuration shown in FIG. 5 is only schematic, and the electronic device may also include more or fewer components than shown in FIG. 5, or has configurations different from those shown in FIG. 5. The components shown in FIG. 5 can be implemented using hardware, software, or a combination of them.

### Embodiment 4

The present disclosure provides a computer readable storage medium on which a computer program is stored, which implements a lossless compression and decompression method for data when executed by the processor 1. For example, implement the following steps:

S101. reading a to-be-compressed file, obtaining raw data in hexadecimal of the file, reading the first eight bytes of the raw data to obtain a first to-be-processed data; S102. determining whether there is at least one digit in the first to-be-processed data that satisfies 0-F; selecting sequentially a half byte from the ninth byte of the raw data and adding it to a tail part of the first to-be-processed data until the condition is met to obtain a second to-be-processed data when the at least one digit in the first to-be-processed data does not satisfy 0-F; or taking the first to-be-processes data as the second to-be-processed data when the at least one digit in the first to-be processed data satisfies 0-F; S103. obtaining a data length based on the second to-be-processed data, converting it to hexadecimal, saving it as data A; obtaining remaining data in the second to-be-processed data except for the last four bytes and saving it as data B; S104. selecting the last four bytes of the second to-be-processed data and performing a rule operation to obtain a third calculation result; converting the third calculation result to hexadecimal and saving it as data C; S105. obtaining a reference digit of the last four bytes of the second to-be-processed data, arranging and combining the reference digit in an orderly manner according to a setting rule, saving a calculation result as all combinations of the third calculation result; searching for a combination of the last four bytes of the second to-be-processed data from a saved combination, obtaining its arrangement rank; converting the arrangement rank to hexadecimal and saving it as data D; S106. obtaining compressed data according to a formula of data A plus data B plus data C plus data D; S107. selecting sequentially next eight bytes from the raw data that has never been read, repeating steps S102-S106 until all bytes have been selected and ending an operation.

If the above functions are implemented in the form of software functional modules and sold or used as independent products, they can be stored on a computer readable storage medium. Based on this understanding, the technical solution of the present application, in essence, or the portion that contributes to the existing technology or the portion of the technical solution, can be reflected in the form of a software product, which is stored in a storage medium, which includes several instructions to enable a computer device (which can be a personal computer, server, or network device, etc.) to perform all or part of the steps of the methods described in various embodiments of the present application. The above storage media includes a USB flash drive, a mobile hard drive, a Read Only Memory (ROM), a Random Access Memory (RAM), a magnetic disks or optical disc, and other media that can store program code.

For those skilled in the art, it is obvious that the present application is not limited to the details of the exemplary embodiments mentioned above, and can be implemented in other specific forms without departing from the spirit or basic features of the present application. Therefore, from any perspective, the embodiments should be regarded as exemplary and non-restrictive. The scope of the present application is limited by the claims rather than the above description, and therefore aims to include all variations within the meaning and scope of the equivalent elements of the claims within the present application. Any drawings in the claims should not be regarded as limiting the claims involved.

What is claimed is:

1. A lossless compression method for data, comprising the following steps:
S101. reading a to-be-compressed file, obtaining raw data in hexadecimal of the file, reading the first eight bytes of the raw data to obtain a first to-be-processed data;
S102. determining whether there is at least one digit in the first to-be-processed data that satisfies 0-F; selecting sequentially a half byte from the ninth byte of the raw data and adding it to a tail part of the first to-be-processed data until the condition is met to obtain a second to-be-processed data when the at least one digit in the first to-be-processed data does not satisfy 0-F; or taking the first to-be-processes data as the second to-be-processed data when the at least one digit in the first to-be processed data satisfies 0-F;
S103. obtaining a data length based on the second to-be-processed data, converting it to hexadecimal, saving it as data A; obtaining remaining data in the second to-be-processed data except for the last four bytes and saving it as data B;
S104. selecting the last four bytes of the second to-be-processed data and performing a rule operation to obtain a third calculation result; converting the third calculation result to hexadecimal and saving it as data C;
S105. obtaining a reference digit of the last four bytes of the second to-be-processed data, arranging and combining the reference digit in an orderly manner according to a setting rule, saving a calculation result as all combinations of the third calculation result; searching for a combination of the last four bytes of the second to-be-processed data from a saved combination, obtaining its arrangement rank; converting the arrangement rank to hexadecimal and saving it as data D;
S106. obtaining compressed data according to a formula of data A plus data B plus data C plus data D;
S107. selecting sequentially next eight bytes from the raw data that has never been read, repeating steps S102-S106 until all bytes have been selected and ending an operation.

2. The lossless compression method for data according to claim 1, wherein the selecting sequentially next eight bytes from the raw data that has never been read, repeating steps S102-S106 until all bytes have been selected and ending an operation comprises:
adding missing digit in 0-F to a tail part of the data when a last selected data supplements eight bytes.

3. The lossless compression method for data according to claim 1, wherein the converting the arrangement rank to hexadecimal and saving it as data D comprises:
supplementing 0 when the data D is less than two bytes.

4. The lossless compression method for data according to claim 1, wherein the selecting the last four bytes of the second to-be-processed data and performing a rule operation to obtain a third calculation result comprises:
selecting the first half byte data and the second half byte data of the last four bytes of the second to-be-processed data, comparing the first half byte data and the second half byte data, performing a larger reduction rule operation to obtain a first calculation result; comparing a size of the first calculation result with the third half byte data, performing the larger reduction rule operation to obtain a second calculation result; repeating sequentially until all data has been calculated, and obtaining the third calculation result.

5. A lossless decompression method for data, comprising the following steps:
S201. reading a to-be-decompressed file in hexadecimal and obtaining a third to-be-processed data;
S202. converting the first byte data of the third to-be-processed data to decimal to obtain a first data; obtaining a calculation length based on the first data, reading data from the second byte of the third to-be-processed data according to the calculation length, obtaining a fourth to-be-processed data, and saving the fourth to-be-processed data as data E;
S203. retrieving the fourth to-be-processed data, determining missing digit in 0-F of the fourth to-be-processed data, and combining according to a setting rule to obtain a second data;
S204. reading data in a first position of the first byte of the third to-be-processed data that has not been read, converting it to decimal to obtain a third data; continuing to read the last two bytes, converting it to decimal to obtain a fourth data;
S205. taking the second data as a reference digit, enumerating all combinations and performing a rule operation, saving a calculation result as all combinations of the third data; reading a ranking of a saved combination and taking it as a combination of the fourth data, saving it as data F;
S206. obtaining decompressed data according to a formula of data E plus data F;
S207. repeating steps S202-S206 for the third to-be-processed data that has not been read until it cannot be read again.

6. The lossless decompression method for data according to claim 5, wherein the obtaining a calculation length based on the first data, reading data from the second byte of the third to-be-processed data according to the calculation length and obtaining a fourth to-be-processed data comprises:
subtracting the first data by eight to obtain a calculation result M;
dividing the calculation result M by two to obtain a calculation result N;
calculating a byte length data of the calculation result N reading from the second byte of the third to-be-processed data.

7. An electronic device, comprising at least one processor, at least one memory and a data bus; wherein the processor and the memory communicate with each other through the data bus; the memory stores a program instruction executed by the processor, which calls the program instruction to execute the method according to claim 1.

8. An electronic device, comprising at least one processor, at least one memory and a data bus; wherein the processor and the memory communicate with each other through the data bus; the memory stores a program instruction executed by the processor, which calls the program instruction to execute the method according to claim 5.

9. A computer-readable storage medium, wherein a computer program is stored thereon, the computer program implements the method according to claim 1 when executed by a processor.

10. A computer-readable storage medium, wherein a computer program is stored thereon, the computer program implements the method according to claim 5 when executed by a processor.
